(19) United States
(12) Patent Application Publication
(10) Pub. No.: US 2026/0312562 A1
(43) Pub. Date: Oct. 8, 2026

(54) RECONFIGURABLE HYBRID LATTICE FILTER SYSTEM

(71) Applicant: Qorvo US, Inc., Greensboro, NC (US)

(72) Inventor: Yazid Yusuf, Orlando, FL (US)

(21) Appl. No.: 19/535,310

(22) Filed: Feb. 10, 2026

Related U.S. Application Data
(60) Provisional application No. 63/782,205, filed on Apr. 2, 2025.

(51) Int. Cl. H03H 9/00; H03H 9/02

(52) U.S. Cl. CPC H03H 9/0023; H03H 9/02; H03H 2009/02165

(57) ABSTRACT

A reconfigurable hybrid lattice filter is disclosed. In one aspect, a filter may have a transformer formed with coils separated by a shielding element. Further, to provide the reconfigurable aspect of the filter, a variable capacitor element may be associated with one of the coils to assist in tuning of an impedance of the filter. Other elements of the filter may be formed from acoustic resonators.

### PRIORITY APPLICATION

The present application is related to U.S. Provisional Patent Application Serial No. 63/782,205, filed on Apr. 2, 2025, and entitled “RECONFIGURABLE HYBRID LATTICE FILTER SYSTEM,” the contents of which are incorporated herein by reference in their entirety.

### BACKGROUND

### I. Field of the Disclosure

The technology of the disclosure relates generally to wideband filters in communication devices and, more particularly, to lattice and hybrid lattice filters using acoustic resonators.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find more bandwidth through which data may be transferred. This increased bandwidth puts pressure on the supporting circuits to operate across larger bands and provides room for innovation.

### SUMMARY

Aspects disclosed in the detailed description include a reconfigurable hybrid lattice filter. In particular, a filter may have a transformer formed with coils separated by a shielding element. Further, to provide the reconfigurable aspect of the filter, a variable capacitor element may be associated with one of the coils to assist in tuning of an impedance of the filter. Other elements of the filter may be formed from acoustic resonators.

In this regard, in one aspect, a hybrid lattice filter is disclosed. The hybrid lattice filter includes an input node, a first element coupled to the input node, and a second element coupled to the input node. The hybrid lattice filter also includes a transformer balun comprising a first coil coupled to the first element, a second coil coupled to the second element; and a center-tap node between the first coil and the second coil. The hybrid lattice filter further includes a tunable capacitor coupled to the center-tap node and a ground.

In another aspect, a method of controlling a hybrid lattice filter is disclosed. The method includes tuning a capacitor coupled to a center-tap node of a transformer balun to cancel capacitance between coils of the transformer balun and providing a signal to the transformer balun through an input node.

In another aspect, a communication device comprising a transceiver is disclosed. The transceiver includes a hybrid lattice filter comprising an input node, a first element coupled to the input node, a second element coupled to the input node, and a transformer balun. The transformer balun comprises a first coil coupled to the first element, a second coil coupled to the second element, and a center-tap node between the first coil and the second coil. The transceiver further includes a tunable capacitor coupled to the center-tap node and a ground.

### BRIEF DESCRIPTION OF THE DRAWINGS

FIG. 1 is a schematic diagram of a conventional hybrid lattice filter using an ideal center-tapped transformer balun;

FIG. 2 is a schematic diagram of a conventional hybrid lattice filter with added capacitors to resonate with inductance from the transformer balun coils and to compensate for non-unity coupling between the coils;

FIG. 3A is a schematic diagram of a reconfigurable hybrid lattice filter according to aspects of the present disclosure;

FIG. 3B is a schematic diagram of the reconfigurable hybrid lattice filter of FIG. 3A with acoustic resonators shown for some elements of the filter;

FIGS. 4A-4C illustrate possible tunable capacitor structures;

FIG. 5 is a side perspective view of a transformer with a shield positioned between the coils according to an aspect of the present disclosure; and

FIG. 6 is a block diagram of a communication device, which may include the reconfigurable hybrid lattice filter according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a," “an,” and “the” are intended to include the plural forms as well unless the context clearly indicates otherwise. It will be further understood that the terms “comprises," “comprising," “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

Aspects disclosed in the detailed description include a reconfigurable hybrid lattice filter. In particular, a filter may have a transformer formed with coils separated by a shielding element. Further, to provide the reconfigurable aspect of the filter, a variable capacitor element may be associated with one of the coils to assist in tuning of an impedance of the filter. Other elements of the filter may be formed from acoustic resonators.

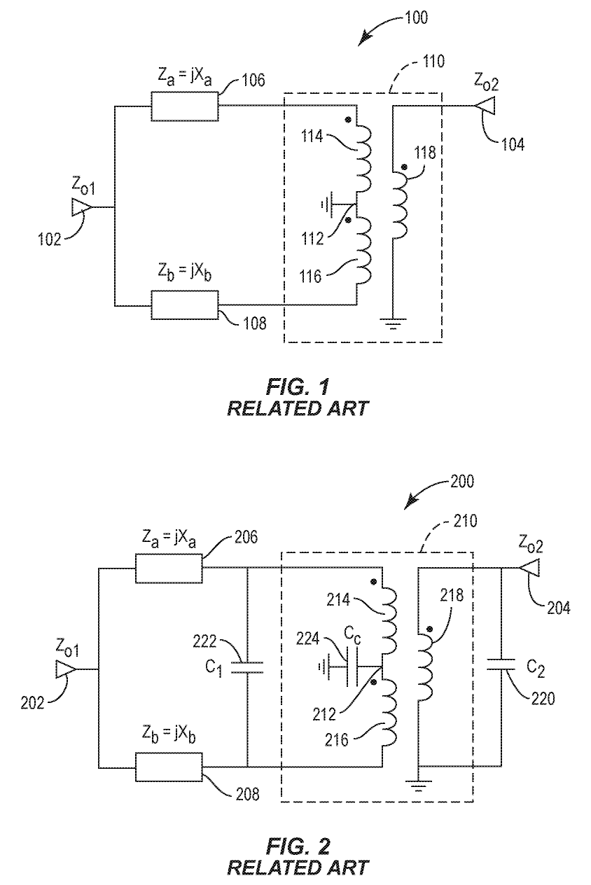

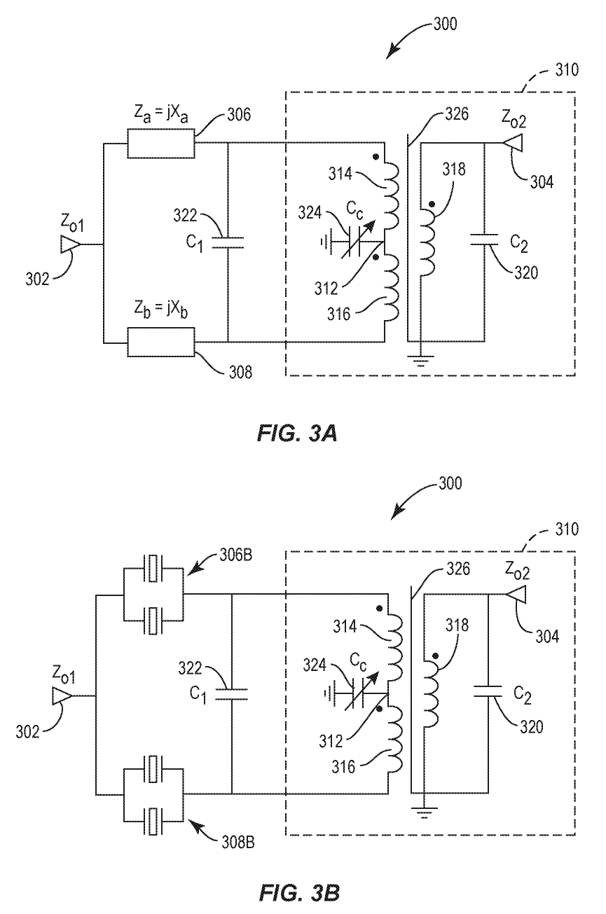

Before addressing aspects of the present disclosure, a brief overview of a hybrid lattice filter is provided with reference to FIGS. 1 & 2. A discussion of aspects of the present disclosure begins below with reference to FIG. 3.

In this regard, FIG. 1 illustrates a hybrid lattice filter 100 with an input node 102 and an output node 104. The input node 102 is coupled to a first element 106 and a second element 108. The first element 106 has an impedance of Zₐ = jXₐ and the second element 108 has an impedance of Z_{b} = jX_{b}. The first element 106 and the second element 108 are coupled to opposite ends of an ideal center-tapped transformer balun 110. It should be appreciated that when Xₐ = X_{b} the filter 100 operates as a stopband filter. However, when Xₐ= -X_{b}, the filter 100 operates as a passband filter.

The center-tapped transformer balun 110 includes a center-tap node 112 between coils 114, 116 that is coupled to ground. The coils 114, 116 couple to another coil 118, which is coupled to the output node 104.

It should be noted that in reality the coils 114, 116, and 118 have some self-inductance which likely makes the transformer balun 110 non-ideal. To compensate, a number of capacitors may be added to resonate the self-inductance as better illustrated in FIG. 2.

In this regard, FIG. 2 illustrates a hybrid lattice filter 200 with an input node 202 and an output node 204. The input node 202 is coupled to a first element 206 and a second element 208. The first element 206 and the second element 208 are coupled to opposite ends of a center-tapped transformer balun 210. The center-tapped transformer balun 210 includes a center-tap node 212 between coils 214, 216. The coils 214, 216 couple to another coil 218, which is coupled to the output node 204. An output capacitor 220 couples the output node 204 to ground, in a parallel with the coil 218. A second capacitor 222 couples the first element 206 to the second element 208 in parallel with the coils 214, 216. Additionally, a third capacitor 224 is used to compensate for the non-unity magnetic mutual coupling between the coils 214, 216.

In practice, for most mobile computing devices, the coils of the transformer will also have a capacitance formed therebetween. An electrostatic shield may be added to cancel this capacitance as illustrated in FIGS. 3A & 3B. In particular, a hybrid lattice filter 300 may have an input node 302 and an output node 304. The input node 302 is coupled to a first element 306 and a second element 308. The first element 306 and the second element 308 are coupled to opposite ends of a center-tapped transformer balun 310.

The center-tapped transformer balun 310 includes a center-tap node 312 between coils 314, 316. The coils 314, 316 couple to another coil 318, which is coupled to the output node 304. An output capacitor 320 couples the output node 304 to ground, in a parallel with the coil 318. A second capacitor 322 couples the first element 306 to the second element 308 in parallel with the coils 314, 316. Additionally, a tunable capacitor 324 is used to compensate for the non-unity magnetic mutual coupling between the coils 314, 316. The tunable capacitor 324 is used to adjust the input impedance of the filter. Modeling shows that the input impedance can be tuned using the tunable capacitor 324 over a wide range with minimal changes to other filter characteristics. An electrostatic shield 326 is positioned between the coils 314, 316 on one side and coil 318 on the other.

It should be noted that the elements 306, 308 may be formed from any number of components, but, in an exemplary aspect, the elements 306, 308 are acoustic resonators 306B, 308B illustrated in FIG. 3B. While not illustrated, a shunt inductor or the like may be used with the acoustic resonators to provide the desired frequency response for the filter 300. Likewise, while parallel acoustic resonators are shown, it should be appreciated that the acoustic resonators may be a plurality of series and/or shunt resonators as is well understood in filter design.

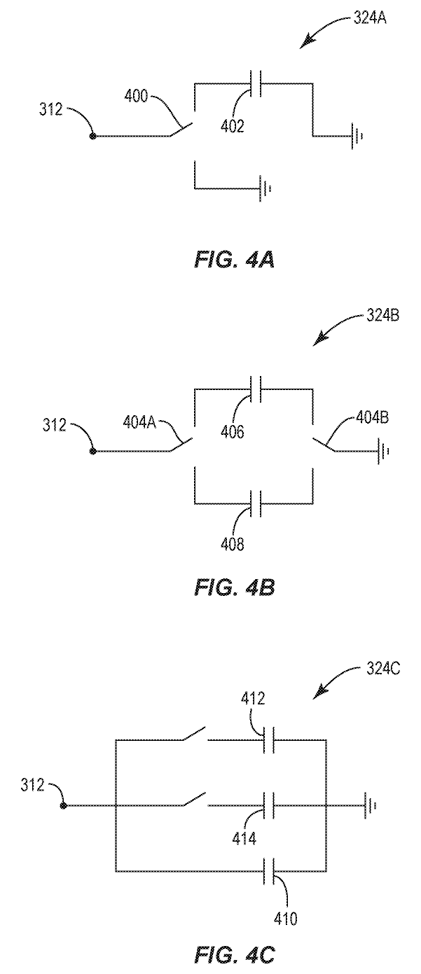

While any number of different variable capacitors could be used, in the interests of robust disclosure, three exemplary tunable capacitors 324A-324C are illustrated in FIGS. 4A-4C respectively. The tunable capacitor 324A includes a switch 400 that selectively couples the node 312 between a ground and a capacitor 402. The tunable capacitor 324B includes switches 404A, 404B that selects between a first capacitor 406 having a first value and a second capacitor 408 having a second different value. The tunable capacitor 324C has a first path that always couples the node 312 to ground through a first capacitor 410 and includes switchable paths with additional capacitors 412, 414 that may be coupled in parallel with the first capacitor 410 to provide different capacitance values. As noted, other tunable capacitor structures may also be used.

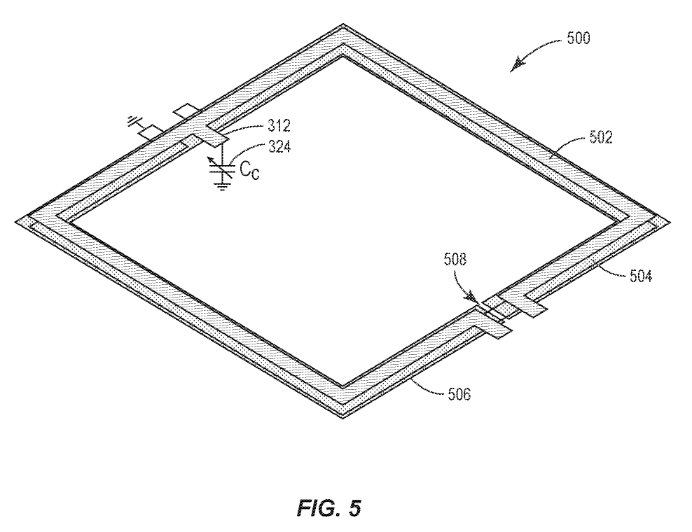

FIG. 5 provides a perspective view of a transformer balun 500 that may be used for the transformer balun 310. In particular, the transformer balun 500 may include a top coil 502 and a bottom coil 504 with a shield 506 therebetween. Note that there may be eddy currents on the shield 506. To combat these currents, a break 508 is provided in the shield 506. For more information about this sort of shield structure, the interested reader is referred to U.S. Patent No. 11,764,747, which is hereby incorporated by reference in its entirety.

The hybrid lattice filter according to aspects disclosed herein is well suited for use in wireless communication devices but may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

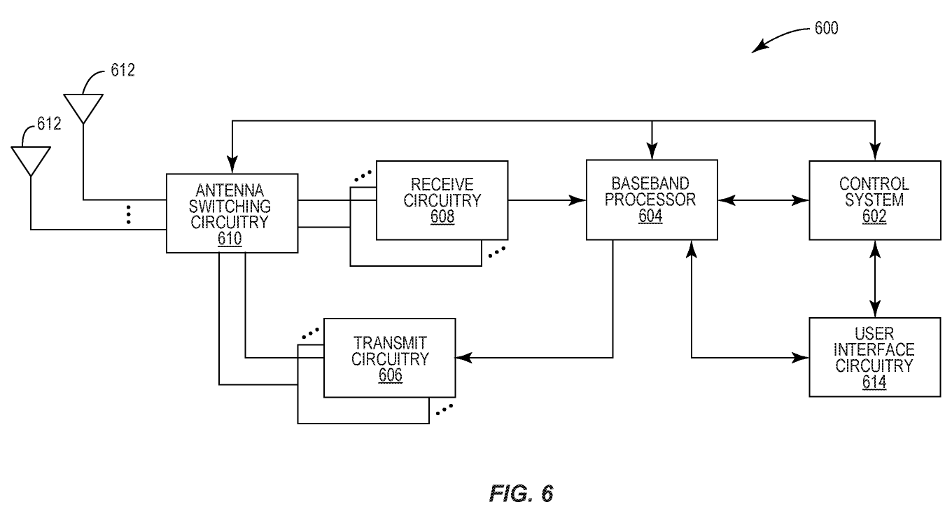

FIG. 6 is a schematic diagram of an exemplary communication device 600 wherein the hybrid lattice filter of the present disclosure can be provided. Herein, the communication device 600 can be any type of communication device, such as those listed above as well as access points, base stations (e.g., eNB or gNB), and any other type of wireless communication devices that support wireless communications, such as cellular, wireless local area network (WLAN), Bluetooth, Ultra-wideband (UWB), and near field communications.

More particularly, the communication device 600 will generally include a control system 602, a baseband processor 604, transmit circuitry 606, receive circuitry 608, antenna switching circuitry 610, multiple antennas 612, and user interface circuitry 614. In a non-limiting example, the control system 602 can be a field-programmable gate array (FPGA) or an application-specific integrated circuit (ASIC), as an example. In this regard, the control system 602 can include at least a microprocessor(s), an embedded memory circuit(s), and a communication bus interface(s). The receive circuitry 608 receives radio frequency signals via the antennas 612 and through the antenna switching circuitry 610 from one or more base stations. A low noise amplifier and a filter (e.g., according to the present disclosure) of the receive circuitry 608 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 604 processes the digitized received signal to extract the information or data bits conveyed in the received signal. This processing typically comprises demodulation, decoding, and error correction operations. The baseband processor 604 is generally implemented in one or more digital signal processors (DSPs) and ASICs.

For transmission, the baseband processor 604 receives digitized data, which may represent voice, data, or control information, from the control system 602, which it encodes for transmission. The encoded data is output to the transmit circuitry 606, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 612 through the antenna switching circuitry 610, usually through a filter such as those disclosed herein. The multiple antennas 612 and the replicated transmit and receive circuitries 606, 608 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A hybrid lattice filter comprising:
an input node;
a first element coupled to the input node;
a second element coupled to the input node;
a transformer balun comprising:
a first coil coupled to the first element;
a second coil coupled to the second element; and
a center-tap node between the first coil and the second coil; and
a tunable capacitor coupled to the center-tap node and a ground.

2. The hybrid lattice filter of claim 1, wherein the first element comprises an acoustic resonator.

3. The hybrid lattice filter of claim 2, wherein the second element comprises a second acoustic resonator.

4. The hybrid lattice filter of claim 1, wherein the tunable capacitor is configured to cancel capacitance formed between the first coil and the second coil.

5. The hybrid lattice filter of claim 1, further comprising a first capacitor coupling the first element to the second element.

6. The hybrid lattice filter of claim 5, further comprising:
an output node coupled to the transformer balun; and
an output capacitor coupling the output node to ground.

7. The hybrid lattice filter of claim 1, wherein the transformer balun comprises a third coil and wherein the first coil and the second coil are inductively coupled to the third coil.

8. The hybrid lattice filter of claim 7, further comprising an electrostatic shield positioned between the first coil and the third coil.

9. The hybrid lattice filter of claim 8, wherein the electrostatic shield comprises a break to prevent current eddies.

10. The hybrid lattice filter of claim 1, wherein the tunable capacitor comprises a switch configured to couple selectively the center-tap node to ground in a first state and to a fixed capacitor in a second state.

11. The hybrid lattice filter of claim 1, wherein the tunable capacitor comprises a switch configured to couple selectively the center-tap node to a first capacitor in a first state and to a second capacitor in a second state wherein the first capacitor has a different capacitance than the second capacitor.

12. The hybrid lattice filter of claim 1, wherein the tunable capacitor comprises a plurality of capacitors in parallel and switches to couple or decouple individual ones of the plurality of capacitors to the center-tap node.

13. The hybrid lattice filter of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

14. A method of controlling a hybrid lattice filter, comprising:
tuning a capacitor coupled to a center-tap node of a transformer balun to cancel capacitance between coils of the transformer balun; and
providing a signal to the transformer balun through an input node.

15. The method of claim 14, wherein providing the signal comprises passing the signal through first and second elements in parallel to the transformer balun.

16. The method of claim 15, wherein passing the signal through the first and second elements comprises passing the signal through first and second acoustic resonators.

17. A communication device comprising a transceiver, the transceiver comprising:
a hybrid lattice filter comprising:
an input node;
a first element coupled to the input node;
a second element coupled to the input node;
a transformer balun comprising:
a first coil coupled to the first element;
a second coil coupled to the second element; and
a center-tap node between the first coil and the second coil; and
a tunable capacitor coupled to the center-tap node and a ground.
